(19) United States
(12) Patent Application Publication
(10) Pub. No.: US 2026/0096409 A1
(43) Pub. Date: Apr. 2, 2026

(54) METHOD OF MANUFACTURING AN INTERCONNECTION FOR AN ELECTRONIC DEVICE

(71) Applicant: STMicroelectronics International N.V., Geneva (CH)

(72) Inventors: Romain COFFY, Voiron (FR); Julien CUZZOCREA, Montbonnot St. Martin (FR)

(73) Assignee: STMicroelectronics International N.V., Geneva (CH)

(21) Appl. No.: 19/346,781

(22) Filed: Oct. 1, 2025

(30) Foreign Application Priority Data
Oct. 1, 2024 (FR) FR2410559

(51) Int. Cl. H01L 23/00; H01L 23/48

(52) U.S. Cl. CPC H10W 20/20; H10W 72/01951; H10W 72/20; H10W 72/921; H10W 90/792

(57) ABSTRACT

A method of manufacturing interconnects for an electronic device includes the steps: a) providing a substrate having a first die, assembled to a second die by hybrid bonding, formed therein, and having conductive areas positioned on top of it, the second die comprising through silicon vias; b) forming conductive wires on the conductive areas, and optionally on the through silicon vias; c) depositing a layer of insulating material on the substrate and on the second die, to encapsulate the conductive wires; d) thinning the layer of insulating material; and e) forming conductive elements on the layer of insulating material, the conductive elements being connected either to the conductive areas or to the vias.

### PRIORITY CLAIM

This application claims the priority benefit of French Application for Patent No. FR2410559, filed on October 1, 2024, the content of which is hereby incorporated by reference in its entirety to the maximum extent allowable by law.

### TECHNICAL FIELD

The present disclosure generally concerns the field of electronic devices and, more particularly, electronic devices comprising dies assembled by direct bonding to substrates ('Die to Wafer') and their integration on external devices by a so-called 'Flip-Chip' transfer technique.

### BACKGROUND

In 'Die-to-Wafer' (D2W) heterogeneous integration, the active surface of an upper die is assembled by hybrid bonding to the active surface of a lower die formed in a substrate. When it is necessary to have connections directly on both dies (for example, to have a power/distribution network without incurring an ohmic drop), through silicon vias (TSVs) are formed in the upper die. Interconnection elements (pillars or bumps) are then formed. Part of the interconnection elements is formed on the TSVs and thus connected to the upper die via the TSVs, and another part of the interconnection elements is formed on conductive areas positioned on the substrate and connected to the lower die. The electronic component thus obtained can then be assembled to an external element, such as a printed circuit board.

However, even with very thin upper dies (typically with a thickness in the range from 20 to 30 µm), the height difference between the base of the different interconnection elements is non-negligible. The formed interconnection elements then are non-coplanar. The mounting of the electronic component on a printed circuit board is then impossible and/or may cause thermomechanical stress within the final device, thus decreasing its reliability over time.

There exists a need to have electronic components comprising a substrate having a die formed therein and having another die mounted on top of it, for example by means of a method of die-to-wafer (D2W) bonding type, the electronic components needing to be able to be easily, durably and reliably, assembled to external elements, typically printed circuit boards, by a so-called flip-chip technique.

### SUMMARY

In an embodiment, a method of manufacturing interconnects for an electronic device comprises the following steps: a) providing an assembly comprising a substrate having a first die formed therein, a first surface of a second die being assembled to the first die by hybrid bonding, the second die comprising through silicon vias emerging onto a second surface of the second die, conductive areas being positioned on the substrate and connected to the first die; b) forming conductive wires on the conductive areas; c) depositing a layer of insulating material on the first surface of the substrate and on the second die so as to encapsulate the conductive wires; d) thinning the layer of insulating material, the conductive wires being accessible from an upper surface of the layer of insulating material; and e) forming conductive elements on the layer of insulating material opposite the conductive areas and opposite the vias, the conductive elements being coupled either to the conductive areas or to the vias, whereby interconnects for the first die and interconnects for the second die are obtained.

According to an embodiment, the method further comprises a step b') during which conductive wires are formed on the through silicon vias, where conductive pads may be arranged between the through silicon vias and the conductive wires.

According to an embodiment, the method comprises, between step d) and step e), a step during which the insulating material is etched to form openings opposite the through silicon vias, and during which the openings are filled with a conductive material to form conductive pads, an upper surface of the insulating material being flush with an upper surface of the conductive pads.

According to an embodiment, the conductive elements are electrically-conductive pillars.

According to an embodiment, step e) is carried out according to the following sub-steps: depositing a seed layer on the layer of insulating material, the seed layer preferably being deposited over the entire wafer; forming a resin layer having openings opposite the conductive areas and opposite the vias; forming the conductive elements through the openings in the resin; and removing the resin and removing the portion of the seed layer not covered by the conductive elements.

According to an embodiment, the conductive elements are solder balls.

According to an embodiment, step e) is carried out according to the following sub-steps: depositing conductive layers on the layer of insulating material opposite the conductive areas and opposite the vias; and forming the conductive elements on the conductive areas.

According to an embodiment, one or a plurality of conductive wires are formed on each connection area of the first die and/or on each conductive pad covering the vias.

In an embodiment, an electronic device comprises: a substrate having a first die formed therein, a first surface of a second die being assembled to the first die by hybrid bonding, the second die comprising through silicon vias emerging onto a second surface of the second die, conductive areas being positioned on the substrate and connected to the first die; interconnects for the first die being formed on the conductive areas, the interconnects comprising from the conductive areas: conductive wires and conductive elements; interconnects for the second die being formed on the through silicon vias, the interconnects comprising conductive elements, where conductive wires may be arranged between the through silicon vias and the conductive elements; and a layer of insulating material covering the first surface of the substrate and the second die and surrounding the conductive wires, the conductive elements being arranged on the layer of insulating material.

According to an embodiment, the conductive elements are solder balls or conductive pillars.

In an embodiment, an assembly comprises a device such as previously defined, and an external device, such as a printed circuit board, comprising conductive areas, the conductive elements being assembled on the conductive areas of the external device.

In an embodiment, for an assembly such as previously defined, the method comprises a step during which the conductive elements are assembled on the conductive areas of the external device, for example during a soldering step.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1G schematically show different steps of a method of manufacturing a D2W-type electronic component according to a specific embodiment;

FIGS. 2A to 2F schematically show different steps of a method of manufacturing a D2W-type electronic component according to another specific embodiment;

FIGS. 3A to 3I schematically show different steps of a method of manufacturing a D2W-type electronic component according to another specific embodiment;

FIG. 4 is a simplified cross-section and side view of a D2W-type electronic component according to another specific embodiment;

FIG. 5 is a simplified cross-section view of a conductive wire on a connection area, according to another specific embodiment,

FIG. 6 is a simplified cross-section view of a D2W-type electronic component assembled to an external element, according to another specific embodiment.

### DETAILED DESCRIPTION

The various elements in the drawings are not necessarily shown to a uniform scale to make them easier to read

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

For clarity, only those steps and elements which are useful to the understanding of the described embodiments have been shown and are described in detail. Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as "front", "back", "top", "bottom", "left", "right", etc., or relative position qualifiers, such as "top", "bottom", "upper", "lower", etc., or orientation qualifiers, such as "horizontal", "vertical", etc., reference is made unless otherwise specified to the orientation of the drawings in a normal position of use.

Unless specified otherwise, the expressions "about", "approximately", "substantially", and "in the order of" signify plus or minus 10%, preferably of plus or minus 5%.

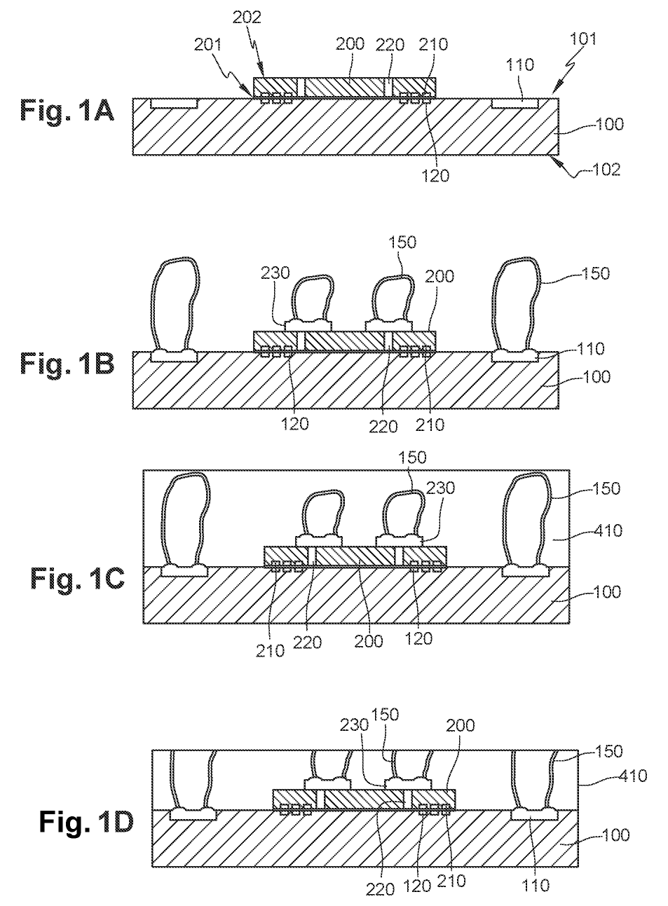

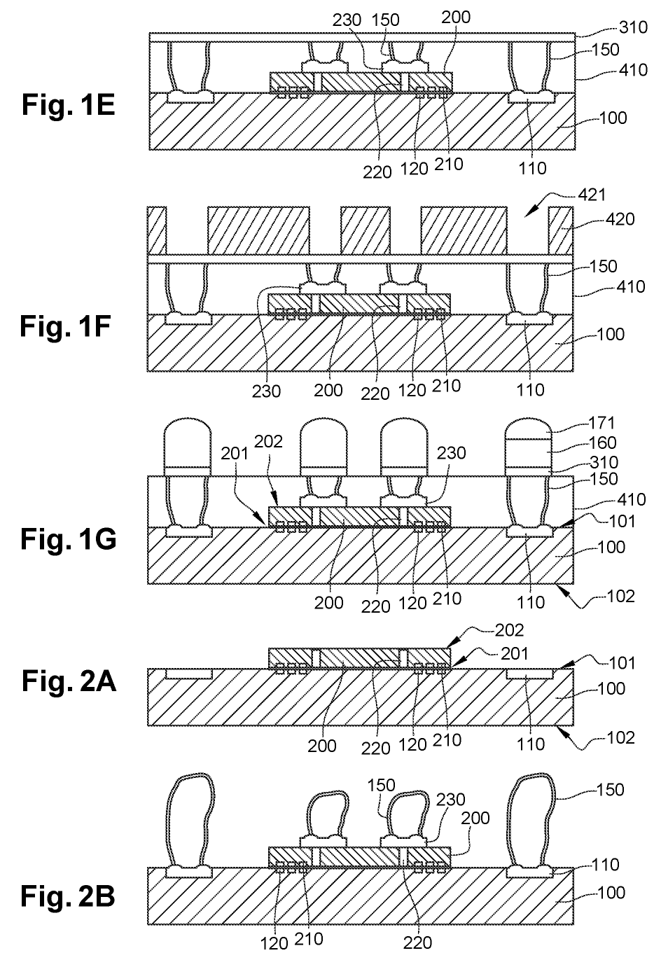

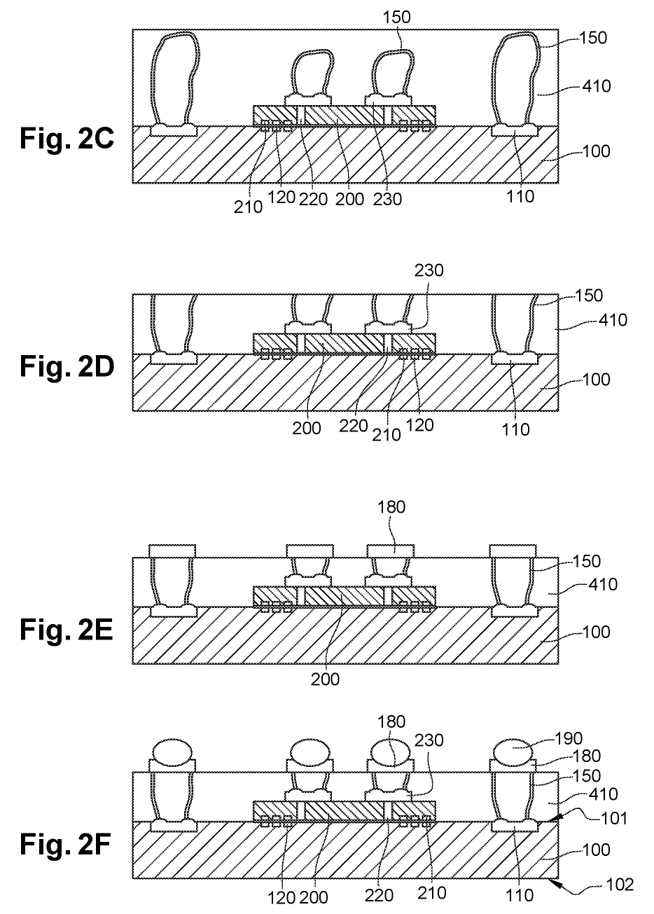

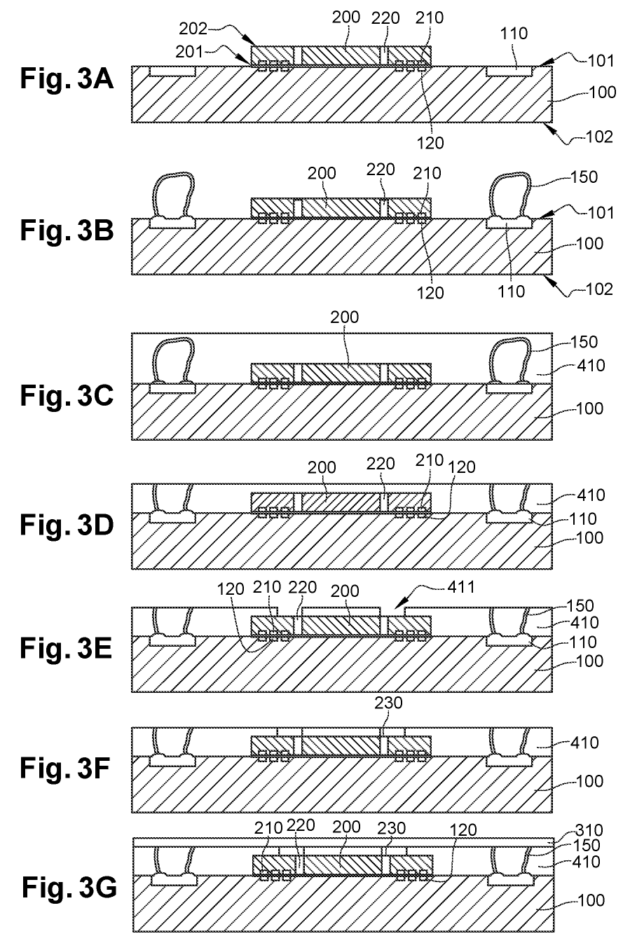

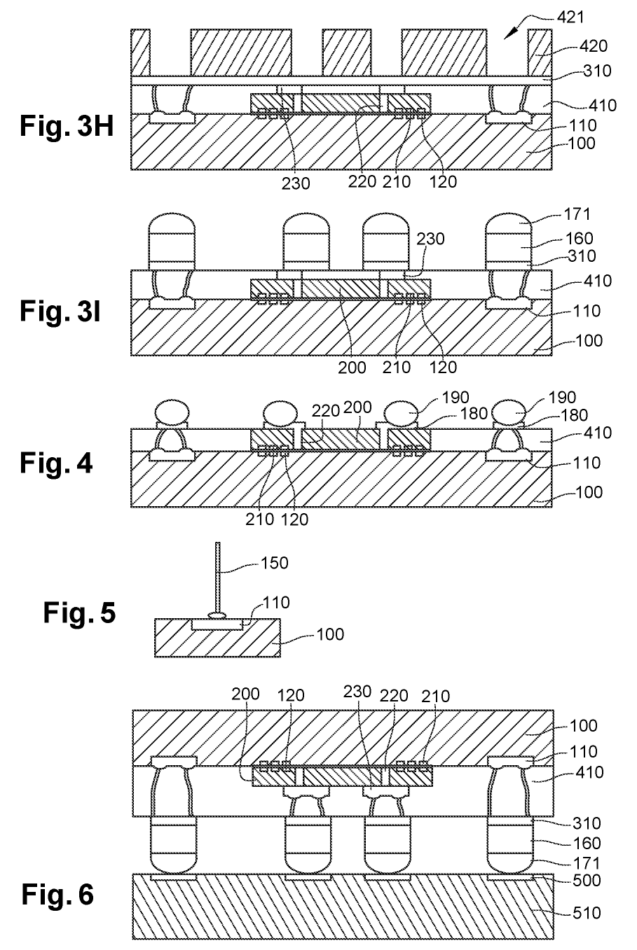

The method of manufacturing interconnects for an electronic component will now be described in detail, with reference to FIGS. 1 to 1G, to FIGS. 2A to 2F, and to FIGS. 3A to 3I, as well as to FIGS. 4 and 5.

The method comprises the following steps: a) providing an assembly comprising a substrate 100 having a first die formed therein, a first surface 101 of a second die 200 being assembled to the first die, for example by hybrid bonding, the second die 200 comprising through silicon vias 220 emerging onto a second surface 201 of the second die 200 and forming conductive contacts, conductive areas 110 being positioned on substrate 100 and connected to the first die (FIGS. 1A, 2A, 3A); b) forming conductive wires 150 opposite conductive areas 110 and electrically connected to the areas 110 (FIGS. 1B, 2B, 3B); c) depositing a layer of insulating material 410 on the substrate and on the second die, the insulating material encapsulating the conductive wires 150 (FIGS. 1C, 2C, 3C); d) thinning the layer of insulating material 410, the conductive wires 150 being accessible from an upper surface of the layer of insulating material 410 (FIGS. 1D, 2D, 3D); e) forming conductive elements 160, 190 on the layer of insulating material 410 opposite conductive areas 110 and opposite vias 220, part of the conductive elements 160, 190 being coupled to the conductive areas 110 and the other part of the conductive elements 160, 190 being coupled to the vias 220, whereby interconnects for the first die and interconnects for the second die 200 are obtained (FIGS. 1G, 2F, 3I).

The upper surfaces of the conductive elements 160, 190 are at a same distance from the first surface 101 of substrate 100.

According to an alternative embodiment, the method may comprise an additional step b'), between step a) and step c), during which conductive wires 150 are also formed opposite vias 220 and electrically connected to vias 220.

Thus, the interconnects of the electronic components are formed in two steps: in a first step, the lower portion of the interconnects of the first die is formed (that is, the conductive wires 150 deposited at step b)), and optionally the lower portion of the interconnects of the second die is formed (that is, the conductive wires 150 deposited at step b')); and in a second step, the conductive elements 160, 190 are deposited to simultaneously form the upper portion of the interconnects of the first die and either the interconnects of the second die 200 or the upper portion of the interconnects of the second die (if step b') is implemented).

The resulting interconnects are coplanar. With such a method, it is possible to achieve a very fine pitch (for example, in the order of 100 µm or even 60 µm).

The assembly provided at step a) comprises substrate 100 having the first die (or lower die) formed therein and the second die 200 (or upper die) (FIGS. 1A, 2A, 3A) mounted on substrate 100.

Substrate 100 comprises a first surface 101 and a second surface 102. Connection pads 120 of the first die are positioned on the first surface of substrate 100. Conductive areas 110, connected to the first die, are also positioned on the first surface 101 of substrate 100, on either side of connection pads 120. Connection pads 120 are used to connect the first die to the second die 200. Conductive areas 110 are used to connect the first die to an external element 500.

The second die 200 comprises a first surface 201 (front side or active surface) and a second surface 202 (back side).

The first surface 201 of the second die 200 is arranged facing the first die. Their active surfaces are arranged facing each other. The first surface 201 of the second die 200 comprises connection pads 210 to connect it to the first die.

The first die and the second die are assembled together by an assembly of die-to-wafer (D2W) type achieved by hybrid bonding. A low die-to-die impedance is obtained.

The second die 200 also comprises through silicon vias (TSVs) 220. Vias 220 run from the first surface 201 of the second die 200 to the second surface 202 of die 200. Through silicon vias 220 emerge onto the second surface 202 of the second die 200 and form conductive contacts used to connect the second die 200 to an external element.

The second die 200 has a thickness, for example, smaller than 60 µm, for example smaller than or equal to 30 µm (for example in the range from 20 to 30 µm) or smaller than 10 µm (for example in the range from 6 to 10 µm).

In the drawings, the assembly of a single first die and a single second die is shown to make the drawings easier to read. However, a plurality of first dies may be formed in substrate 100 and a plurality of second dies 200 may be assembled to the plurality of first dies. In order to separate the different first die/second die assemblies, the method comprises a step, after step e), during which substrate 100 is cut.

During step b), conductive wires 150 are formed on the conductive areas 110 (FIGS. 1B, 2B, 3B).

Before implementing step b'), during which conductive wires 150 are formed on vias 220, a conductive pad 230 will preferably be deposited on vias 220 so as to have a larger surface area to form conductive wires 150 (FIGS. 1B, 2B). Steps b) and b') may be carried out simultaneously or consecutively.

Conductive wires 150 may be formed by a wire bonding technique.

In the various drawings showing the steps of the electronic component manufacturing method, a U-shaped conductive wire is formed on the conductive areas and, optionally, on conductive pads 230. However, as shown in FIG. 5, it would be possible to form one or a plurality of straight wires 150 on each conductive area 110 and optionally on each conductive pad 230. It would also be possible to form conductive wires coupling two conductive areas 110 and/or two conductive pads 230, the conductive wires 150 being cut during the thinning step in order to avoid short-circuits in the device.

Conductive wires 150 are, for example, made of copper or gold. They have a diameter in the range, for example, from 20 to 30 µm, for example in the order of 25 µm.

At step c), a layer of insulating material 410 is deposited on substrate 100 and on the second die 200. The insulating material fully encapsulates the conductive wires 150. The layer of insulating material 410 totally covers the first surface 101 of substrate 100 and the second surface 202 of the second die 200.

Insulating material 410 is, for example, a polymer, preferably a polyimide (PI) or a polybenzoxazole (PBO), or an oxide.

The layer of insulating material 410 acts as a buffer layer, and absorbs part of the mechanical stress applied to the conductive wires 150.

During step d), insulating material 410 is thinned. The conductive wires being completely embedded in the layer of insulating material 410 during step c), this enables to make the upper portion of conductive wires 150 accessible and, optionally, to level their height (FIG. 3D). A planar insulating material/conductive wire upper surface is obtained.

In the case where step b') is not implemented, after step d), the method comprises a step during which insulating material 410 is etched to form openings 411 facing vias 220 (FIG. 3E). Openings 411 are then filled with a conductive material to form conductive pads 230, so as to have the upper surface of the insulating material at the same level as the upper surface of the conductive material (FIG. 3F). In other words, the upper surface of the conductive material and the upper surface of the insulating material are coplanar.

The openings formed in insulating material 410 are made, for example, by photolithography or by laser engraving.

The conductive material forming the conductive pads 230 is, for example, copper. The copper may be coated with a layer, for example made of gold or nickel, to prevent its oxidation.

At step e), the conductive elements 160, 190 are formed, on the one hand, on the conductive wires 150 positioned on the conductive areas 110 and, on the other hand, on vias 220 or on the conductive wires 150 positioned on vias 220.

At the end of this step, the interconnects between the second die 200 and the first die are formed.

A portion of conductive elements 160, 190 covers passivation layer 420, which improves the resistance to mechanical stress.

According to an alternative embodiment, for example shown in FIGS. 1E to 1G and 3G to 3I, step e) may be carried out according to the following sub-steps: depositing a seed layer 310 to cover the accessible conductive wires 150, seed layer 310 being preferably deposited over the entire wafer (FIGS. 1E, 3G); forming, on seed layer 310, a resin layer 420 having openings 421 (FIGS. 1F, 3H); forming conductive elements 160 through the openings 421 of resin layer 420, and then applying a solder layer; removing resin 420 and then the portion of seed layer 310 not covered by conductive elements 160; preferably, carrying out a reflow to melt the solder layer and form solder pads 171 on conductive elements 160 (FIGS. 1G, 3I).

According to this alternative embodiment, conductive elements 160 are, for example, in the form of pillars. They may be copper pillars. The height of resin layer 420 is preferably greater than the desired height of the pillars. The upper portion of the pillars is thus well defined.

The solder layer may be made of a tin-based alloy, for example, an SnAgCu alloy.

Seed layer 310 enables to grow the conductive elements 160 by electrodeposition. Seed layer 310 is, for example, made of TiCu.

The resin is, for example, resist. Conventional photolithography techniques may be used to form a resin layer comprising openings.

According to another alternative embodiment, for example shown in FIGS. 2E and 2F, step e) is carried out according to the sub-steps: forming conductive layers 180 on conductive wires 150, the conductive layers 180 being connected to the conductive wires 150 (FIG. 2E); forming conductive elements 190 on conductive layers 180 (FIG. 2F).

According to this variant, the conductive elements 190 are solder balls. They may be deposited through a mask or by an automatic ball placement tool.

Conductive layers 180 are made of metal or of a metal alloy. They are, for example, made of aluminum ('AluCap') or of NiAu.

Solder balls 190 may be made of a tin-based alloy, for example, a SnAgCu alloy.

It is possible to combine these different alternative embodiments, for example to obtain the structure shown in FIG. 4. This structure is obtained by implementing the steps shown in FIGS. 3A to 3F and then forming conductive layers 180 on vias 220 (the conductive layers 180 being connected to vias 220) and on the conductive wires 150 formed on the conductive areas 110. A conductive element 190 is then formed on the conductive layers 180.

As mentioned above, after the implementation of steps a) to e), a cutting step, in which the dies are separated, may be carried out.

The resulting electronic device comprises (FIG. 1G, 2F, FIG. 3I, and FIG. 4): a first interconnection group formed on substrate 100 and connected to the first conductive areas 110, and a second interconnection group formed on the second surface 202 of the second die 200 and connected to vias 220.

The first interconnection group enables to couple the die of substrate 100 to external element 500, and the second interconnection group enabling to couple the second die 200 to external element 500.

The interconnects of the first interconnection group comprise a first portion (or lower portion) formed of the conductive wires 150 having a second portion (or upper portion), formed of conductive element 160, 190, resting thereon. More particularly, the interconnects of the first interconnection group may comprise, successively from conductive areas 110: conductive wires 150, a seed layer 310, a conductive element 160, optionally a solder pad 171. Conductive element 160 may have a surface area identical to the surface area of seed layer 310 (FIGS. 1G, 3I).

Alternatively, the interconnects of the first interconnection group may successively comprise, starting from conductive areas 110: a seed layer 310, conductive wires 150, a conductive layer 180, a conductive element 190 (FIG. 2F, FIG. 4). Conductive element 190 may have a surface area larger than the surface area of conductive layer 180.

The interconnects of the second interconnection group comprise conductive element 160, 190. More particularly, the interconnects of the second interconnection group successively comprise, starting from through silicon vias 220: a conductive pad 230 in contact with through silicon vias 220, conductive wires 150, a seed layer 310, a conductive element 160, optionally a solder pad 171 (FIG. 1G).

Alternatively, the interconnects of the second interconnection group may comprise, successively from through silicon vias 220: a conductive pad 230, conductive wires 150, a conductive layer 180, a conductive element 190 (FIG. 2F). Conductive element 190 may have a surface area larger than the surface area of conductive layer 180.

Alternatively, the interconnects of the second interconnection group may comprise, successively from through silicon vias 220: a conductive pad 230, a seed layer 310, a conductive element 160, optionally a solder pad 171 (FIG. 3I).

Alternatively, the interconnects of the second interconnection group may comprise, successively from through silicon vias 220: a conductive layer 180, a conductive element 190 (FIG. 4).

The conductive elements 160, 190 of the first interconnection group and of the second interconnection group rest on passivation layer 420, which decreases the mechanical stress on the interconnects.

The upper surfaces of conductive elements 160, 190 are at the same distance from the first surface 101 of substrate 100, which facilitates the positioning and the assembly of the interconnects with an external element 500, such as a printed circuit board (PCB) or a laminate substrate (FIG. 6). In FIG. 6, the electronic component of FIG. 1G is shown, but obviously the other previously-described components could also be used.

Since the interconnects are coplanar, the electronic device can be assembled by any conventional technique, for example by wire bonding or by bumping.

In particular, the method of assembling the device to an external element 510 comprises a step during which the interconnects are aligned and brought into contact with the conductive areas 500 of device 510 and a step, for example of soldering, during which the interconnects are bonded to the conductive areas 500 of external element 510. The soldering ensures electrical and mechanical contact between the device and the external element. It can be achieved either by adding additional solder paste or with a solder flux which deoxidizes and holds the device during the step of reflow of the solder balls 190 or of the solder pads 171 on conductive areas 510.

The electronic device may be an analog memory device. It can be used in systems requiring a high number of inputs/outputs (I/O). It is particularly advantageous in the automotive field (especially for a Microcontroller Unit (MCU)) or for personal ('consumer') objects.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing interconnects for an electronic device, comprising the following steps:
a) providing an assembly comprising a substrate having a first die formed therein, wherein conductive areas are positioned on the substrate and connected to the first die, wherein a first surface of a second die is assembled to the first die by hybrid bonding, and wherein the second die comprises through silicon vias emerging onto a second surface of the second die;
b) forming conductive wires on the conductive areas;
c) encapsulating the conductive wires in a layer of insulating material deposited on the first surface of the substrate and on the second die;
d) thinning the layer of insulating material to make the conductive wires accessible from an upper surface of the layer of insulating material; and
e) forming conductive elements on the layer of insulating material opposite the conductive areas and opposite the through silicon vias, the conductive elements being coupled either to the conductive areas or to the through silicon vias, whereby interconnects for the first die and interconnects for the second die are obtained.

2. The method according to claim 1, wherein substrate comprises a wafer having the first die formed therein and the assembly comprises a die-to-wafer type assembly with the second die assembled to the wafer.

3. The method according to claim 1, wherein forming conductive wires on the conductive areas comprises using bonding wires, each bonding wire having a first end and a second end attached to a same conductive area.

4. The method according to claim 1, wherein step b) further comprises: forming conductive wires on the through silicon vias, and arranging conductive pads between the through silicon vias and the conductive wires.

5. The method according to claim 4, wherein forming conductive wires on the through silicon vias comprises using bonding wires, each bonding wire having a first end and a second end attached to a same conductive pad over the through silicon via.

6. The method according to claim 4, wherein one or a plurality of conductive wires are formed on each conductive pad covering the through silicon vias.

7. The method according to claim 1, further comprising, between step d) and step e), etching the insulating material to form openings opposite the through silicon vias, and further comprising filling the openings with a conductive material to form conductive pads, an upper surface of the insulating material being flush with an upper surface of the conductive pads.

8. The method according to claim 1, wherein the conductive elements are electrically-conductive pillars.

9. The method according to claim 8, wherein step e) comprises the following steps:
depositing a seed layer on the layer of insulating material, the seed layer preferably being deposited over the entire wafer;
forming a resin layer having openings opposite the conductive areas and opposite the through silicon vias;
forming the conductive elements through the openings in the resin; and
removing the resin and removing the portion of the seed layer not covered by the conductive elements.

10. The method according to claim 1, wherein the conductive elements are solder balls.

11. The method according to claim 10, wherein step e) comprises the following steps:
depositing conductive layers on the layer of insulating material opposite the conductive areas and opposite the through silicon vias; and
forming the conductive elements on the conductive areas.

12. The method according to claim 1, further comprising forming one or a plurality of conductive wires on each connection area of the first die.

13. An electronic device, comprising:
a substrate having a first die formed therein and including conductive areas being positioned on the substrate and connected to the first die;
a second die having a first surface assembled to the first die by hybrid bonding, the second die comprising through silicon vias emerging onto a second surface of the second die;
interconnects for the first die formed on the conductive areas, the interconnects for the first die comprising, starting from the conductive areas: conductive wires and conductive elements;
interconnects for the second die formed on the through silicon vias, the interconnects for the second die comprising conductive elements, where conductive wires may be arranged between the through silicon vias and the conductive elements; and
a layer of insulating material covering the first surface of the substrate and the second die and surrounding the conductive wires, the conductive elements being arranged on the layer of insulating material.

14. The device according to claim 13, wherein substrate comprises a wafer having the first die formed therein and the second die is assembled to the wafer to form a die-to-wafer type assembly.

15. The device according to claim 13, wherein the conductive elements are one of solder balls or conductive pillars.

16. The device according to claim 13, further comprising:
a first interconnection group on the conductive pads of the substrate comprising a first portion formed by conductive wire and a second portion formed by conductive element resting on the conductive wire; and
a second interconnection group on the conductive contacts of the through silicon vias on the second surface of the second die comprising conductive element on the conductive contacts of the through silicon vias on the second surface of the second die.

17. The device according to claim 13, further comprising:
a first interconnection group on the conductive pads of the substrate comprising a first portion formed by conductive wire and a second portion formed by conductive element resting on the conductive wire; and
a second interconnection group on the conductive contacts of the through silicon vias on the second surface of the second die comprising a first portion formed by conductive wire and a second portion formed by conductive element resting on the conductive wire.

18. An assembly, comprising:
the device of claim 13; and
an external device comprising a printed circuit board and including conductive areas, wherein the conductive elements are assembled on the conductive areas of the external device.

19. A method of manufacturing the assembly of claim 18, the method comprising a step during which the conductive elements are assembled on the conductive areas of the external device using a soldering step.
